(19) United States
(12) Patent Application Publication
(10) Pub. No.: US 2025/0157998 A1
(43) Pub. Date: May 15, 2025

(54) MICROMECHANICAL COMPONENT AND CORRESPONDING PRODUCTION METHOD

(71) Applicant: Robert Bosch GmbH, Stuttgart (DE)

(72) Inventors: Dorothea Papathanassiou, Neuffen (DE); Hans-Peter Baer, Pfullingen (DE); Jan Stiedl, Pliezhausen (DE); Tobias Henn, Stuttgart (DE)

(21) Appl. No.: 18/836,084

(22) PCT Filed: Mar. 1, 2023
(86) PCT No.: PCT/EP2023/055201

§ 371 Date: Aug. 6, 2024

(30) Foreign Application Priority Data
Mar. 8, 2022 (DE) 10 2022 202 299.8

(51) Int. Cl. H01L 25/16; B81B 7/00; B81C 1/00; H01L 21/56; H01L 23/00; H01L 23/31; H10D 80/30

(52) U.S. Cl. CPC H01L 25/16; B81B 7/0025; B81C 1/00793; H01L 23/3121; H01L 24/27; H01L 24/29; H01L 24/32; H01L 24/48; H01L 24/73; B81B 2201/0264; B81B 2207/012; H01L 21/565; H01L 2224/27515; H01L 2224/29018; H01L 2224/2929; H01L 2224/32225; H01L 2224/48091; H01L 2224/48225; H01L 2224/73215; H01L 2924/1433; H01L 2924/1461; H10D 80/30

(57) ABSTRACT

A micromechanical component and a corresponding production method. The micromechanical component is equipped with a substrate, a function chip which is attached to the substrate and has a main surface facing away from the substrate, wherein one or more bond pads are provided on the main surface, which are bonded to the substrate by a respective bond wire. On the main surface or above the main surface of the function chip, a cover chip, which is formed from a chip material that has a diffusion-inhibiting effect on halogen ions located in the mold compound, is attached as a diffusion barrier to a mold package. The cover chip covers the main surface substantially completely. The micromechanical component further includes the mold package, in which the function chip is packaged together with the cover chip.

### FIELD

The present invention relates to a micromechanical component and to a corresponding production method.

### BACKGROUND INFORMATION

Although any micromechanical components can be used, the present invention and the underlying problem are explained with reference to micromechanical sensor devices, in particular silicon-based pressure sensors or microphones, which comprise a sensor chip and a circuit chip.

Housings for micromechanical pressure sensors and microphones require open access to a detection zone of the sensor chip, the detection zone being formed, for example, by a membrane. A possible implementation is a so-called premold housing or mold-premold housing (MPM). In the latter, the ASIC circuit chip is overmolded and, at the same time, a cavity is generated during molding. The micromechanical sensor chip is inserted into the cavity. This design can be implemented with both SOIC (small outline integrated circuit) and LGA (land grid array) packaging. The mold-premold housing is advantageous in comparison to the pure premold housing in that the ASIC circuit chip is overmolded and thus better protected from mechanical and environmental influences.

German Patent Application No. DE 10 2009 002 376 A1 describes a multi-chip sensor module and a corresponding production method, for example for a sensor element and a corresponding ASIC circuit chip. The electrical contacts of the components are arranged in different planes. After or when embedding in an embedding compound, a through-connection to the contacts of the component in the embedding compound is created. The components are subsequently contacted in an electrically conductive manner.

German Patent Application DE 10 2011 084 582 A1 describers a micromechanical sensor device with a substrate, a circuit chip attached to the substrate, a mold package in which the circuit chip is packaged, wherein the mold package has a cavity, in which a sensor chip is provided, above the circuit chip, and wherein the mold package has a through-hole, through which an electrical connection of the sensor chip is guided to the substrate, within the cavity. German Patent Application No. DE 10 2011 084 582 A1 likewise describes a corresponding production method.

FIG. 7 is a schematic cross-sectional view for explaining a micromechanical sensor device and a corresponding production method according to German Patent Application No. DE 10 2011 084 582 A1.

An ASIC circuit chip 2 is glued to a substrate 1, e.g., a printed circuit board, and bond pads 30 are electrically connected on the main surface 2a to the printed circuit board 1 by bond wires 3. The ASIC circuit chip 2 is subsequently overmolded with a mold compound 4, wherein the molding tool forms a cavity 5 in the mold compound 4. In this cavity 5, the pressure sensor MEMS chip 6 is subsequently glued and potted with a gel 7. For example, the pressure sensor MEMS chip 6 is likewise bonded by means of a bond wire 3a to the printed circuit board 1 through a through-hole in the cavity 5.

Such pressure sensors are used in various applications (e.g., diesel particulate filters, manifold air pressure, airbag, . . . ).

A known problem for such mold packages is impurities in the mold compound, which can never be entirely avoided in compound production. Impurities with substances or their reaction products, which can cause corrosion on the ASIC circuit chip 2, are particularly critical. A relevant example in this respect is CaCl particles 20 in the mold compound, which, in conjunction with harsh ambient conditions in diesel particulate filter applications (high temperatures and high moisture content, long service times with active current feed). These particles can result in field failures caused by corrosion with dentrite formation.

It could be shown that the field failures are caused by CaCl impurities (CaCl particles 20) in the mold compound, which accumulate during the molding process in the direct spatial environment of the corrosion-susceptible bond pads 30. Cl-ions dissolved from the CaCl particles 20 by moisture then cause corrosion in active sensor operation, resulting in the formation of dentrites, which ultimately leads to component failure.

FIG. 8 is a schematic cross-sectional view for explaining an exemplary micromechanical sensor device and a corresponding production method with a modification of FIG. 7.

In this modification, it was attempted to use a top coat 10 to spatially separate the susceptible main surface 2a of the ASIC circuit chip 2 from the mold compound 4 (and thus from possible Cl-containing impurities) and as a diffusion barrier to protect the main surface 2a from the halogen ions.

The top coat 10 is a potting compound, which is dispensed onto the main surface 2a of the ASIC circuit chip 2 after the wire bonding process and is subsequently thermally cured. The sensor is subsequently molded as in the standard process flow and the MPM housing is formed in the process. The top coat 10 spatially separates the main surface 2a of the ASIC circuit chip 2 from the mold compound 4 with the CaCl particles 20.

The requirement of the maximum permitted total component height of the MPM housing limits the mold coverage over the ASIC circuit chip 2 (typically approximately 300 μm) and consequently also the maximum possible layer thickness of the top coat 10 (≤160 μm) that must be complied with in order not to interfere with the molding process.

Due to the rheology of top-coat potting compounds, they cannot be dispensed as a homogeneous layer with constant thickness over the ASIC circuit chip 2 but typically form a domed cover. It is critical that the layer thickness of the top coat 10 at the chip edge at which the bond pads 30 to be protected are located on the main surface 2a is very thin. However, a reduction in the layer thickness adversely affects the protective effect of the top coat 10.

A large number of different potting compounds for the top coat 10 were evaluated and assessed with respect to their protective effect against the formation of corrosion by mold impurities. It was shown that none of the examined top coat options offers complete protection against corrosion.

With the most suitable top coats, a time delay in the start of the corrosion failures in comparison to reference groups with unprotected ASIC circuit chips 2 was achieved in provocation tests (targeted application of impurities on the main surface 2a before overmolding, subsequent active operation of the sensors in moisture storage), but the failure rates of the top coat groups matched those of the control groups after 1000h active moisture storage.

The reason for the failures of the ASIC circuit chips 2 protected by top coat 10 is that the potting compounds do not sufficiently protect against the diffusion of mobile Cl ions from mold impurities to the main surface 2a in the presence of moisture.

The effect of the top coat 10 as a diffusion barrier between the mold impurities and the main surface 2a is thus not sufficient. The reason is presumably the composition of the top-coat potting compounds. They typically consist mainly of silica fillers enclosed in an epoxy resin die (or similar organic dies). It is believed that the resin die does not sufficiently suppress diffusion of Cl ions or other halogen ions.

### SUMMARY

The present invention provides a micromechanical component and a corresponding production method.

Preferred developments and example embodiments of the present invention are disclosed herein.

An underlying idea of the present invention is that a chip diffusion barrier, which protects the main surface of the function chip from corrosion-promoting halogen ions from impurity particles in the mold compound, is provided on the function chip.

In order to achieve the protective effect, the main surface of the function chip is thus covered toward the mold compound by a chip which is made of a suitable material and prevents the diffusion of halogen ions from impurity particles in the mold compound. Suitable chip materials include, for example, but not exclusively, silicon chips, glass chips, ceramic chips, or plastic chips that suppress the diffusion of halogen ions. The approach according to the present invention thus makes it possible to eliminate the aforementioned corrosion phenomena.

The method according to the present invention can be implemented with the conventional molding tool, wherein only an additional step for applying the halogen-diffusion-inhibiting chip is required. In other words, an implementation in the conventional process flow can be represented very simply.

For the production of the proposed arrangement according to the present invention, only established standard materials and standard methods from integrated circuits packaging are used (e.g., silicon wafer or glass wafer, back-thinning the wafer by grinding, separating the chips by mechanical sawing, mounting of the chips with FOW or FOD with standard die-attach processes).

The assembly of the cover chips can, for example, take place with standard die-attach systems and is therefore extremely efficient since more than 1000 sensors/hour can be manufactured with a single system.

The arrangement according to an example embodiment of the present invention can be designed to comply with the exemplary requirements described above with respect to total component height, ASIC mold coverage and minimal mold coverage of the protective barrier. Usable in this case is, for example, a silicon cover chip or glass cover chip of 80 μm thickness, which is applied onto the ASIC with an 80 μm thick FOW. The 80 μm FOW thickness is sufficient to embed the bond connections, and the total thickness of the protection arrangement of cover chip and FOW can be designed to be sufficiently small at 160 μm not to adversely affect the molding process.

According to a preferred development of the present invention, the function chip is a circuit chip, wherein the mold package has a cavity above the function chip, in which cavity a sensor chip is attached, which in particular comprises a pressure sensor and/or a microphone and/or an acceleration sensor and/or a rotation rate sensor and/or an optical sensor. Such sensor devices can be designed to be particularly robust through the present invention.

According to a further preferred development of the present invention, the cover chip is attached to the main surface via an adhesion layer. In particular, a FOW or FOD technique, but also a dispensing technique, with a liquid adhesion film is applicable for this purpose.

According to a further preferred development of the present invention, the adhesion layer is produced from a thermoplastic material. The connection between the function chip and the cover chip can thus be produced by means of a thermal method.

According to a further preferred development of the present invention, the adhesion layer surrounds the function chip laterally and extends to the substrate. This achieves protection against halogen ions on all sides.

According to a further preferred development of the present invention, the cover chip projects laterally beyond the function chip. This allows the covered surface to be larger and the barrier effect to be increased.

According to a further preferred development of the present invention, the cover chip has a cavern, which surrounds the function chip and which is attached to the substrate via an adhesion layer. This provides a special protective effect, in particular also with regard to the compressive load during the molding process.

### BRIEF DESCRIPTION OF THE DRAWINGS

Further features and advantages of the present invention are explained below on the basis of example embodiments with reference to the figures.

FIG. 1 shows a schematic cross-sectional view for explaining a micromechanical component and a corresponding production method according to a first example embodiment of the present invention.

FIG. 2 shows a schematic cross-sectional view for explaining a micromechanical component and a corresponding production method according to a second example embodiment of the present invention.

FIGS. 3A-3D show an exemplary method step sequence for forming the FOW circuit chip cover according to FIG. 1, according to the present invention.

FIG. 4 shows a schematic cross-sectional view for explaining a micromechanical component and a corresponding production method according to a third example embodiment of the present invention.

FIG. 5 shows a schematic cross-sectional view for explaining a micromechanical component and a corresponding production method according to a fourth example embodiment of the present invention.

FIG. 6 shows a schematic cross-sectional view for explaining a micromechanical component and a corresponding production method according to a fifth example embodiment of the present invention.

FIG. 7 shows a schematic cross-sectional view for explaining a micromechanical sensor device and a corresponding production method according to the related art.

FIG. 8 shows a schematic cross-sectional view for explaining an exemplary micromechanical sensor device and a corresponding production method with a modification of the related art according to FIG. 7.

### DETAILED DESCRIPTION OF EXAMPLE EMBODIMENTS

In the figures, identical reference signs denote identical or functionally identical elements.

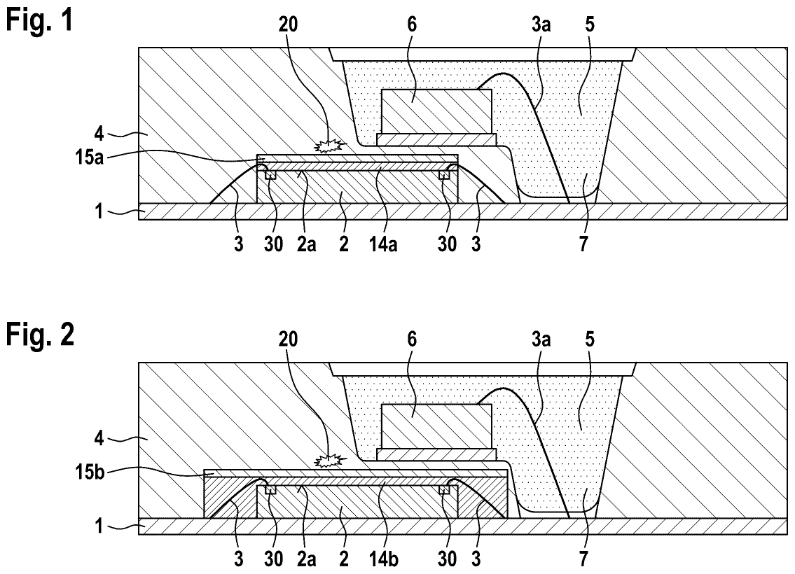

FIG. 1 shows a schematic cross-sectional view for explaining a micromechanical component and a corresponding production method according to a first embodiment of the present invention.

In FIG. 1, reference number 1 denotes a substrate, e.g., a printed circuit board, for the micromechanical component, a pressure sensor device in the present case.

A circuit chip 2 as a function chip with a main surface 2a facing away from the substrate 1 is attached to the substrate 1, for example by gluing, wherein one or more bond pads 30 are provided on the main surface 2a. The bond pads 30 are connected via a respective bond wire 3 to corresponding contacts (not shown) of the substrate 1.

Subsequently, a cover chip 15a, which is formed from a chip material that has a diffusion-inhibiting effect on halogen ions located in the mold compound 4, is attached, as a diffusion barrier to the later mold package 4, to the main surface 2a of the circuit chip 2. Examples of such a chip material are silicon, glass, ceramic, plastic, etc.

In this first embodiment, the cover chip 15a is attached to the main surface 2a via an adhesion layer 14a, which is produced from a thermoplastic material, wherein the cover chip 14a, together with the thermally softened adhesion layer 14a located thereon, is applied onto the main surface 2a. This can be achieved, for example, by bringing the substrate 1 to an elevated temperature beforehand, e.g., 140° C. After the application, the adhesion layer 14a is cured to form a solid composite of circuit chip 2 and cover chip 15a.

Finally, the cover chip 15a with the underlying adhesion layer 14a completely covers the main surface 2a of the circuit chip 2, wherein the lateral region of the circuit chip 2 is exposed. Such a cover is also referred to as a FOW (film over wire) cover.

Next, a mold package 4, in which the circuit chip 2 is packaged together with the cover chip 15a, is provided by means of a corresponding molding tool.

Furthermore, in this embodiment, a cavity 5 is formed in the mold package 4, above the circuit chip 2 and at a distance from the cover chip 15a, in which cavity a sensor chip 6 is attached, which in particular comprises a pressure sensor and/or a microphone and/or an acceleration sensor and/or a rotation rate sensor and/or an optical sensor. The size of the cavity 5 can be determined by the molding tool. For example, a standard LGA molding press with insert in the tool may be used.

The sensor chip 6 is then connected by means of a bond connection 3a through a through-hole in the mold package to a contact (not shown) on the substrate 1.

Finally, passivation with a gel 7 is provided within the cavity 5. Optionally, in a further method step, a lid may be attached, which has a through-hole that makes external pressure access to the detection zone of the sensor chip 6 possible.

The cover chip 15a applied onto the circuit chip 2 is quasi-impenetrable for the diffusion of halogen ions in an aqueous solution. It thus effectively protects the main surface 2a with the bond pads 30 against halogen ions washed out of particles in the mold compound and thus highly effectively suppresses corrosion by such mold impurities.

FIG. 2 shows a schematic cross-sectional view for explaining a micromechanical component and a corresponding production method according to a second embodiment of the present invention.

The second embodiment differs from the first embodiment in that the cover chip 15b projects laterally beyond the circuit chip 2, and in that the adhesion layer 14b, which is connected to the cover chip 15b, surrounds the circuit chip 2 laterally and extends to the substrate 1.

This can be achieved in that, in the heated application of the cover chip 15b with the adhesion layer 14b, the circuit chip 2 is pushed into the adhesion layer 14b so that the latter completely encompasses it. Such a cover is also referred to as a FOD (film over die) cover.

Otherwise, the second embodiment is identical to the first embodiment.

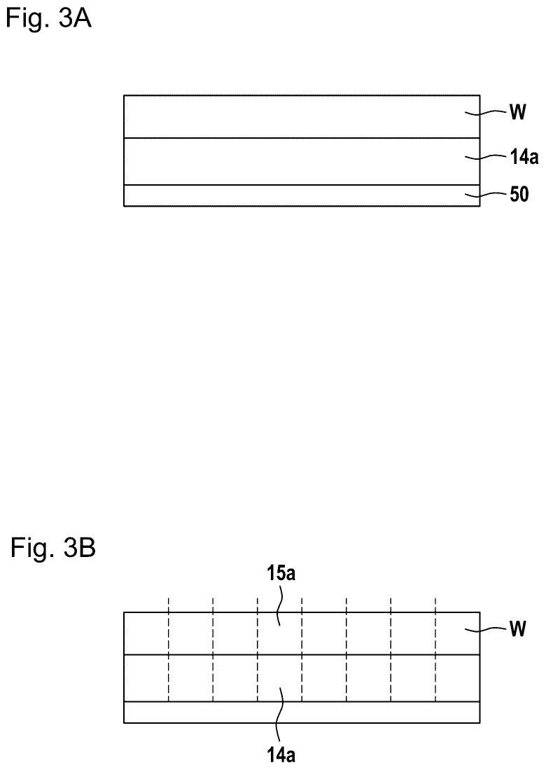

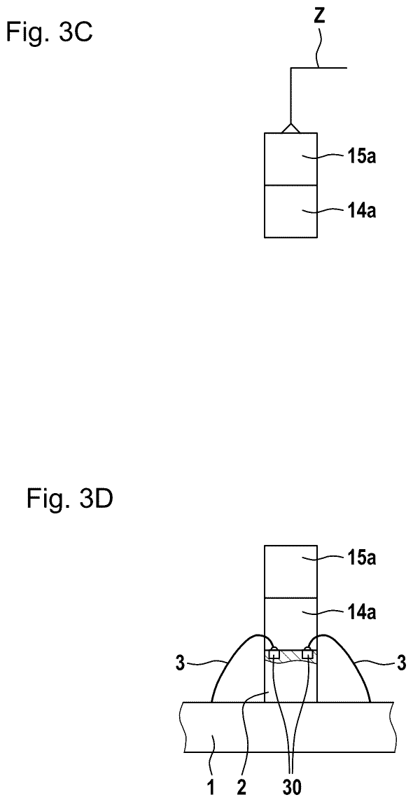

FIGS. 3A-3D show an exemplary method step sequence for forming the FOW circuit chip cover according to FIG. 1.

According to FIG. 3A, a wafer W, which is coated over the entire surface on its rear side with the adhesion layer 14a, is provided for the cover chips. A sawing film 50 is applied onto the adhesion layer 14a.

According to FIG. 3B, the cover chips 15a, together with the corresponding region of the adhesion layer 14a, are cut out of the wafer W, which may previously be ground to the corresponding target thickness.

By means of a gripping tool Z, the cover chips 15a with the adhesion layer 14a are removed from the sawing film 50 and transported to the circuit chip 2 to be protected, as shown in FIG. 3C.

In the arrangement described in FIG. 1, the cover chips 15a are glued to the circuit chip 2 to be protected by means of “film-over-wire” (FOW) after the bonding process, and the FOW is thermally cured, as shown in FIG. 3D.

In the arrangement described in FIG. 2, the cover chips 15b are glued to the circuit chip 2 to be protected by means of “film-over-die” (FOD) after the bonding process. The only difference to the method according to FIGS. 3A-3D is that the cover chips 15b have a greater surface area in comparison to the circuit chip 2 to be protected, and that the adhesion layer 14b has a greater thickness in order to be able to embed the circuit chip 2 to be protected such that it is completely encompassed laterally.

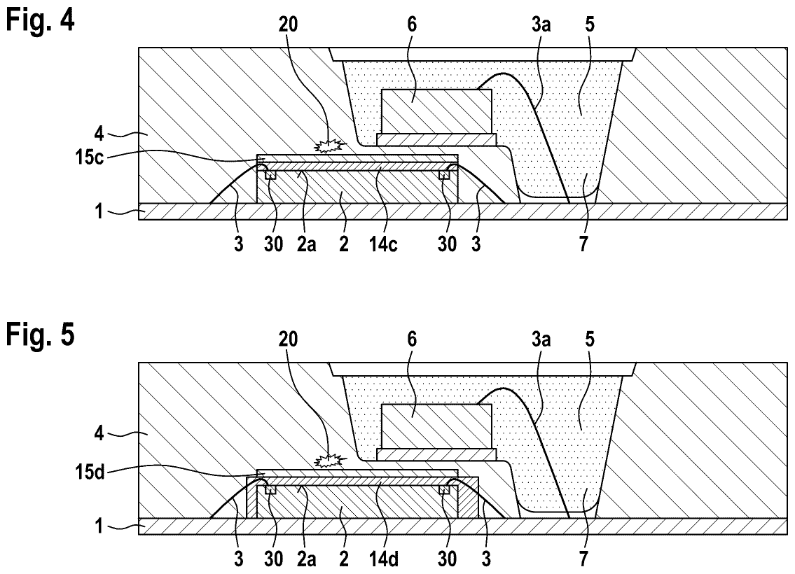

FIG. 4 shows a schematic cross-sectional view for explaining a micromechanical component and a corresponding production method according to a third embodiment of the present invention.

Alternatively, according to FIG. 4, there is also the possibility of mounting the cover chip 15c with a liquid adhesion layer 14c on the circuit chip 2. The liquid adhesion layer 14c is dispensed onto the main surface 2a for this purpose.

This possibility may be used, for example, if a supplier does not have any FOW or FOD available for logistic reasons, or if they cannot be used due to product-specific requirements for other reasons. In this approach, however, it must be noted that the cover chip assembly must take place with precise height control in order not to damage the bond connections.

Otherwise, the third embodiment is identical to the first embodiment.

FIG. 5 shows a schematic cross-sectional view for explaining a micromechanical component and a corresponding production method according to a fourth embodiment of the present invention.

The fourth embodiment differs from the third embodiment in that the liquid adhesion layer 14d is dispensed over the main surface in such a way that the circuit chip 2 is completely laterally encompassed thereby, before the cover chip 15d is placed on top.

Otherwise, the fourth embodiment is identical to the third embodiment.

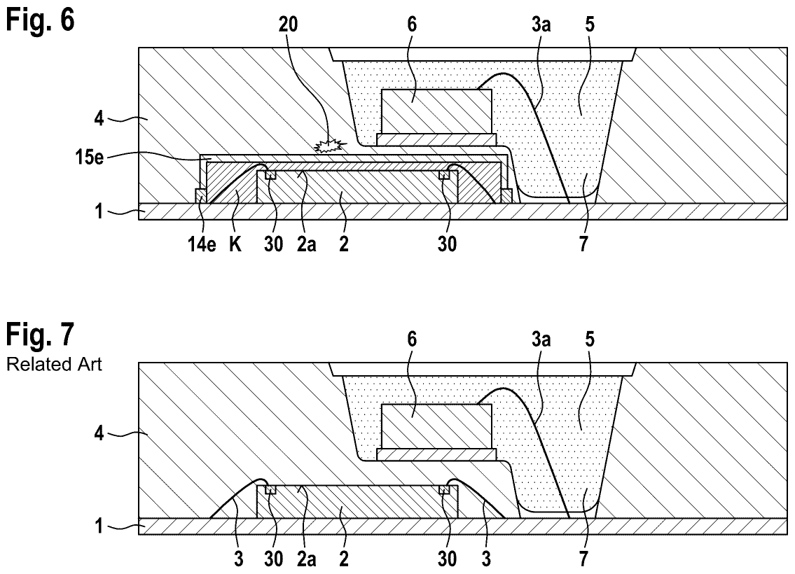

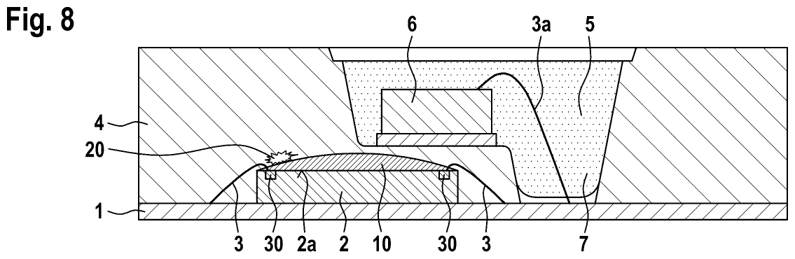

FIG. 6 shows a schematic cross-sectional view for explaining a micromechanical component and a corresponding production method according to a fifth embodiment of the present invention.

Instead of the above-described embodiments, in which a flat cover chip 15a-d protects the main surface 2a, a structured cover chip 15e with a rear cavity K can also be used in the fifth embodiment.

Cover chips 15e with such rear cavities K can be produced at the wafer level at low cost, for example by deep reactive ion etching (DRIE).

In the arrangement shown in FIG. 6, such a structured cover chip 15e is mounted with a liquid adhesion layer 14e, previously dispensed on the substrate 1, as a cap over the circuit chip 2 to be protected. The thus constructed cap then protects the circuit chip 2 on all five molded sides against halogen ions from corresponding corrosive impurities in the mold compound.

Although the present invention has been described with reference to preferred exemplary embodiments, it is not limited thereto. In particular, the materials and topologies mentioned are only exemplary and not limited to the examples explained.

Although the description above is with respect to a pressure sensor, the present invention may, inter alia, also be used for microphones, acceleration sensors, optical sensors, rotation rate sensors, etc., which require external access to the outside world but must be protected against environmental influences.

The present invention can also generally be used for circuit chip arrangements with or without a sensor chip with a different function chip, i.e., not only for micromechanical sensor devices but for any mold-packaged micromechanical components with a function chip. Examples of other function chips include electromechanical or electrochemical function chips.

In the above embodiments, the use of a cover chip for implementing an in-package silicon diffusion barrier to protect application-specific integrated circuit chips (ASIC) from corroding media is described, by way of example, for MPM housings. However, the arrangement for ASIC protection is not limited to MPM housings but can be used in all mold packages and open cavity packages (e.g., microphone housings).

1-15. (canceled)

16. A micromechanical component, comprising:
a substrate;
a function chip which is attached to the substrate and has a main surface facing away from the substrate, wherein one or more bond pads are provided on the main surface and are bonded to the substrate via a respective bond wire;
a cover chip, which is formed from a chip material that has a diffusion-inhibiting effect on halogen ions located in a mold compound, is attached, as a diffusion barrier to a mold package, to the main surface or above the main surface of the circuit chip, wherein the cover chip substantially completely covers the main surface; and
the mold package, in which the function chip is packaged together with the cover chip.

17. The micromechanical component according to claim 16, wherein the function chip is a circuit chip, wherein the mold package has a cavity above the function chip, a sensor chip being attached in the cavity, wherein the sensor chip includes a pressure sensor and/or a microphone and/or an acceleration sensor and/or a rotation rate sensor and/or an optical sensor.

18. The micromechanical component according to claim 16, wherein the cover chip is attached to the main surface via an adhesion layer.

19. The micromechanical component according to claim 18, wherein the adhesion layer is produced from a thermoplastic material.

20. The micromechanical component according to claim 18, wherein the adhesion layer laterally surrounds the function chip and extends to the substrate.

21. The micromechanical component according to claim 16, wherein the cover chip projects laterally beyond the function chip.

22. The micromechanical component according to claim 16, wherein the cover chip has a cavity which surrounds the function chip, and the cover chip is attached to the substrate via an adhesion layer.

23. A method for producing a micromechanical component, comprising the steps of:
providing a substrate;
attaching a function chip with a main surface facing away from the substrate, to the substrate, wherein one or more bond pads are provided on the main surface;
bonding the bond pads to the substrate via a respective bond wire;
attaching a cover chip, which is formed from a chip material that has a diffusion-inhibiting effect on halogen ions located in the mold compound, as a diffusion barrier to a mold package, to the main surface or above the main surface of the circuit chip, wherein the cover chip substantially completely covers the main surface; and
providing a mold package, in which the function chip is packaged together with the cover chip.

24. The method according to claim 23, wherein a cavity is formed in the mold package above the function chip, in which cavity a sensor chip is attached, the sensor chip including a pressure sensor and/or a microphone and/or an acceleration sensor and/or a rotation rate sensor and/or an optical sensor.

25. The method according to claim 23, wherein the cover chip is attached to the main surface via an adhesion layer.

26. The method according to claim 25, wherein the adhesion layer is produced from a thermoplastic material and the cover chip is attached, together with the thermally softened adhesion layer located thereon, to the main surface.

27. The method according to claim 25, wherein the adhesion layer is dispensed in liquid form onto the main surface, the cover chip is arranged thereon, and the adhesion layer is subsequently cured.

28. The method according to claim 26, wherein the adhesion layer is configured to laterally surround the function chip and extend to the substrate.

29. The method according to claim 23, wherein the cover chip is configured and attached in such a way that the cover chip projects laterally beyond the function chip.

30. The method according to claim 23, wherein the cover chip has a cavity, which is configured and attached in such a way that the cavity surrounds the function chip, wherein the cover chip is attached to the substrate via an adhesion layer.
